(19) United States
(12) Patent Application Publication
(10) Pub. No.: US 2025/0380577 A1
(43) Pub. Date: Dec. 11, 2025

(54) DISPLAY DEVICE AND METHOD OF MANUFACTURING DISPLAY DEVICE

(71) Applicant: Japan Display Inc., Tokyo (JP)

(72) Inventors: Sho YANAGISAWA, Tokyo (JP); Jun HANARI, Tokyo (JP); Hidekazu MIYAKE, Tokyo (JP)

(73) Assignee: Japan Display Inc., Tokyo (JP)

(21) Appl. No.: 19/231,716

(22) Filed: Jun. 9, 2025

(30) Foreign Application Priority Data
Jun. 10, 2024 (JP) 2024-093714

(51) Int. Cl. H10K 59/122; H10K 59/12

(52) U.S. Cl. CPC H10K 59/122; H10K 59/1201

(57) ABSTRACT

According to one embodiment, a display device includes first and second subpixels arrayed in a first direction, a rib layer having first and second pixel apertures, and a partition between the subpixels. The partition is split into first and second partitions by a slit extending in a second direction. The first partition includes a lower portion having first and second side surfaces and an upper portion having first and second end portions. The first end portion protrudes from the first side surface. The second end portion does not protrude from the second side surface or protrudes from the second side surface with a protrusion length shorter than a protrusion length of the first end portion from the first side surface.

### CROSS-REFERENCE TO RELATED APPLICATION

This application is based upon and claims the benefit of priority from Japanese Patent Application No. 2024-093714, filed Jun. 10, 2024, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. In this type of display devices, a technique for improving the yield is required.

### BRIEF DESCRIPTION OF THE DRAWINGS

FIG. 1 is a diagram showing a configuration example of a display device according to the first embodiment.

FIG. 2 is a schematic plan view showing an example of layouts of subpixels.

FIG. 3 is a schematic cross-sectional view of the display device along the III-III line of FIG. 2.

FIG. 4 is a schematic plan view showing some elements of the display device according to the first embodiment.

FIG. 5 is a schematic plan view showing an example of configurations applicable to a partition according to the first embodiment.

FIG. 6 is a schematic plan view showing an example of configurations applicable to the partition and a sealing layer according to the first embodiment.

FIG. 7 is a schematic cross-sectional view of the display device along the VII-VII line of FIG. 6.

FIG. 8 is a schematic cross-sectional view showing a first partition according to the first embodiment in enlarged manner.

FIG. 9 is a flowchart showing an example of a manufacturing method of the display device according to the first embodiment.

FIG. 10A is a schematic cross-sectional view showing a manufacturing process of the display device according to the first embodiment.

FIG. 10B is a schematic cross-sectional view showing a process following FIG. 10A.

FIG. 10C is a schematic cross-sectional view showing a process following FIG. 10B.

FIG. 10D is a schematic cross-sectional view showing a process following FIG. 10C.

FIG. 11A is a schematic cross-sectional view showing a partition immediately after the formation.

FIG. 11B is a schematic cross-sectional view showing a step of removing an end portion of an upper portion along a slit.

FIG. 11C is a schematic cross-sectional view showing a process following FIG. 11B.

FIG. 11D is a schematic cross-sectional view showing a process following FIG. 11C.

FIG. 11E is a schematic cross-sectional view showing a process following FIG. 11D.

FIG. 12A is a schematic cross-sectional view showing a process of forming a pixel aperture in a rib layer.

FIG. 12B is a schematic cross-sectional view showing a process following FIG. 12A.

FIG. 13A is a schematic cross-sectional view showing a process of removing the rib layer on a terminal portion.

FIG. 13B is a schematic cross-sectional view showing a process following FIG. 13A.

FIG. 14A is a schematic cross-sectional view showing a process of forming a display element.

FIG. 14B is a schematic cross-sectional view showing a process following FIG. 14A.

FIG. 14C is a schematic cross-sectional view showing a process following FIG. 14B.

FIG. 14D is a schematic cross-sectional view showing a process following FIG. 14C.

FIG. 15 is a diagram for explaining an effect of the first embodiment.

FIG. 16 is a diagram for explaining an effect of the first embodiment.

FIG. 17 is a schematic cross-sectional view showing a first partition according to the second embodiment.

FIG. 18 is a schematic cross-sectional view showing a first partition according to the third embodiment.

FIG. 19 is a schematic cross-sectional view showing a first partition according to the fourth embodiment.

### DETAILED DESCRIPTION

In general, according to one embodiment, a display device includes a first subpixel and a second subpixel that are arrayed in a first direction, a rib layer including a first pixel aperture located in the first subpixel and a second pixel aperture located in the second subpixel, and a partition located between the first subpixel and the second subpixel and provided above the rib layer. The partition is split into a first partition on the first subpixel side and a second partition on the second subpixel side by a slit extending in a second direction intersecting the first direction. The first partition includes a lower portion having a first side surface on the first subpixel side and a second side surface on the slit side and an upper portion having a first end portion on the first subpixel side and a second end portion on the slit side and provided above the lower portion. The first end portion protrudes from the first side surface. The second end portion does not protrude from the second side surface or protrudes from the second side surface with a protrusion length shorter than a protrusion length of the first end portion from the first side surface.

Further, according to an embodiment, a display device manufacturing method includes forming a first lower electrode and a second lower electrode respectively in a first subpixel and a second subpixel that are arrayed in a first direction, forming a rib layer covering the first lower electrode and the second lower electrode, forming a first partition on the subpixel side and a second partition on the second subpixel side between the first subpixel and the second subpixel, the first partition and the second partition each having a lower portion provided above the rib layer and an upper portion having end portions respectively protruding from side surfaces of the lower portion and split by a slit extending in a second direction intersecting the first direction, and removing the end portions of the upper portion along the slit at least one of the first partition and the second partition.

Each embodiment can improve the yield of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to one another are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

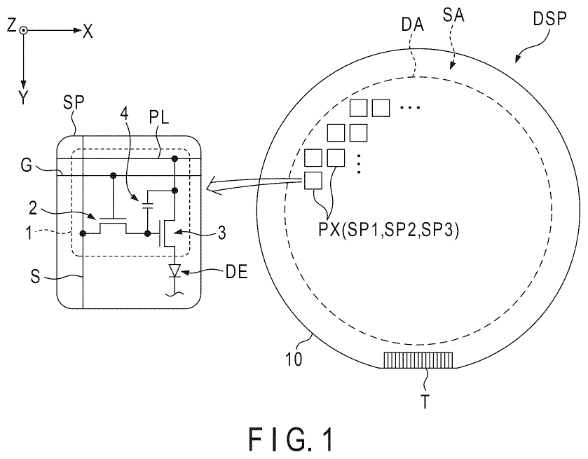

FIG. 1 is a diagram showing a configuration example of a display device DSP according to the first embodiment. The display device DSP comprises an insulating substrate 10. The substrate 10 has a display area DA which displays an image, and a surrounding area SA around the display area DA. The substrate 10 may be glass or a resinous film having flexibility.

In the present embodiment, the substrate 10 and the display area DA are circular as seen in plan view. It should be noted that the shape of each of the substrate 10 and the display area DA in plan view is not limited to a circle and may be another shape such as a rectangle, a square, or an oval.

The display area DA comprises a plurality of pixels PX arrayed in matrix in the X-direction and the Y-direction. Each pixel PX includes a plurality of subpixels SP that display different colors. The present embodiment assumes a case where each pixel PX includes a blue subpixel SP1 (the first subpixel), a green subpixel SP2 (the second subpixel), and a red subpixel SP3 (the third subpixel). Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit that applies voltage and signals for driving the display device DSP is connected to the terminal portion T.

Each subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements consisting of thin-film transistors.

In the display area DA, a plurality of scanning lines G, which supply the pixel circuit 1 of each subpixel SP with scanning signals, a plurality of signal lines S, which supply the pixel circuit 1 of each subpixel SP with video signals, and a plurality of power lines PL are provided. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of the source electrode and the drain electrode of the pixel switch 2 is connected to the signal line S. The other is connected to the gate electrode of the drive transistor 3 and the capacitor 4. In the drive transistor 3, one of the source electrode and the drain electrode is connected to the power line PL and the capacitor 4. The other one is connected to the display element DE.

The configuration of the pixel circuit 1 is not limited to the example shown in the figure. For example, the pixel circuit 1 may comprise more thin-film transistors and capacitors.

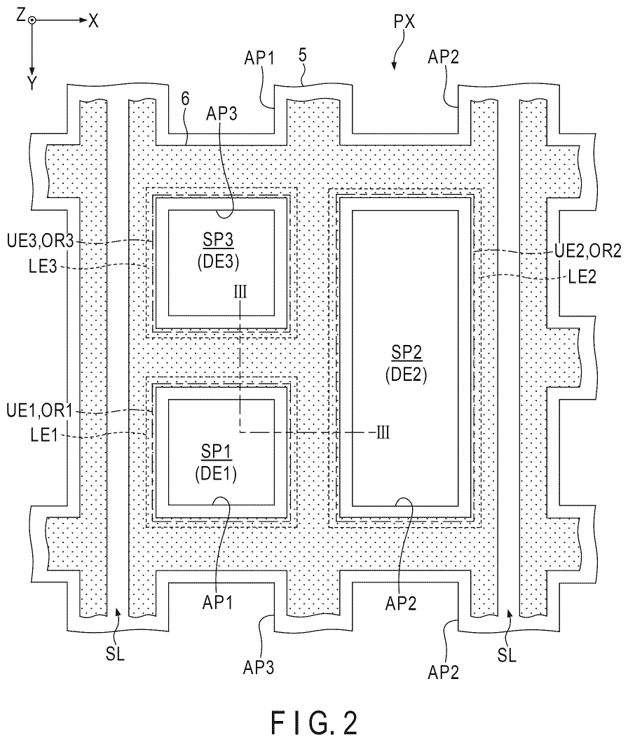

FIG. 2 is a schematic plan view showing an example of layouts of the subpixels SP1, SP2, and SP3 that constitute one pixel PX. In the example of

FIG. 2, the subpixels SP1 and SP3 are arrayed in the Y-direction. Each of the subpixels SP1 and SP3 is adjacent to the subpixel SP2 in the X-direction.

When the subpixels SP1, SP2, and SP3 are arrayed in this layout, in the display area DA, a column in which the subpixels SP1 and SP3 are alternately arrayed in the Y direction and a column in which the plurality of subpixels SP2 are repeatedly arrayed in the Y direction are formed. These columns are alternately arrayed in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 (the first to third pixel apertures) in the subpixels SP1, SP2, and SP3, respectively. In the example of FIG. 2, the pixel apertures AP1 and AP3 have rectangular shapes of the same size in plan view. On the other hand, the pixel aperture AP2 is a rectangle elongated in the Y-direction relative to the pixel apertures AP1 and AP3. The shapes of the pixel aperture AP1, AP2, and AP3 are not limited to these examples.

The subpixel SP1 comprises a lower electrode LE1 (the first lower electrode), an upper electrode UE1 (the first upper electrode), and an organic layer OR1 (the first organic layer). Each of these overlaps the pixel aperture AP1. The subpixel SP2 comprises a lower electrode LE2 (the second lower electrode), an upper electrode UE2 (the second upper electrode), and an organic layer OR2 (the second organic layer). Each of these overlaps the pixel aperture AP2. The subpixel SP3 comprises a lower electrode LE3 (the third lower electrode), an upper electrode UE3 (the third upper electrode), and an organic layer OR3 (the third organic layer). Each of these overlaps the pixel aperture AP3. Of the lower electrode LE1, the upper

electrode UE1, and the organic layer OR1, the portions that overlap the pixel aperture AP1 constitute a display element DE1 (the first display element) of the subpixel SP1. Of the lower electrode LE2, the upper electrode UE2, and the organic layer OR2, the portions that overlap the pixel aperture AP2 constitute a display element DE2 (the second display element) of the subpixel SP2. Of the lower electrode LE3, the upper electrode UE3, and the organic layer OR3, the portions that overlap the pixel aperture AP3 constitute a display element DE3 (the third display element) of the subpixel SP3. Each of the display elements DE1, DE2, and DE3 may further include a cap layer as described later. The rib layer 5 surrounds each of these display elements DE1, DE2, and DE3.

A conductive partition 6 is provided above the rib layer 5. The partition 6 functions as lines that supply the upper electrodes UE1, UE2, and UE3 with common voltage. The partition 6 overlaps the rib layer 5 as a whole and has a planar shape similar to that of the rib layer 5. The partition 6 surrounds the subpixels SP1, SP2, and SP3.

As described in detail later, the partition 6 has a plurality of slits SL extending in the Y direction. In the example of FIG. 2, the subpixels SP1, SP2, and SP3 constituting one pixel PX are provided between two slits SL. However, the arrangement of the slits SL is not limited to this example.

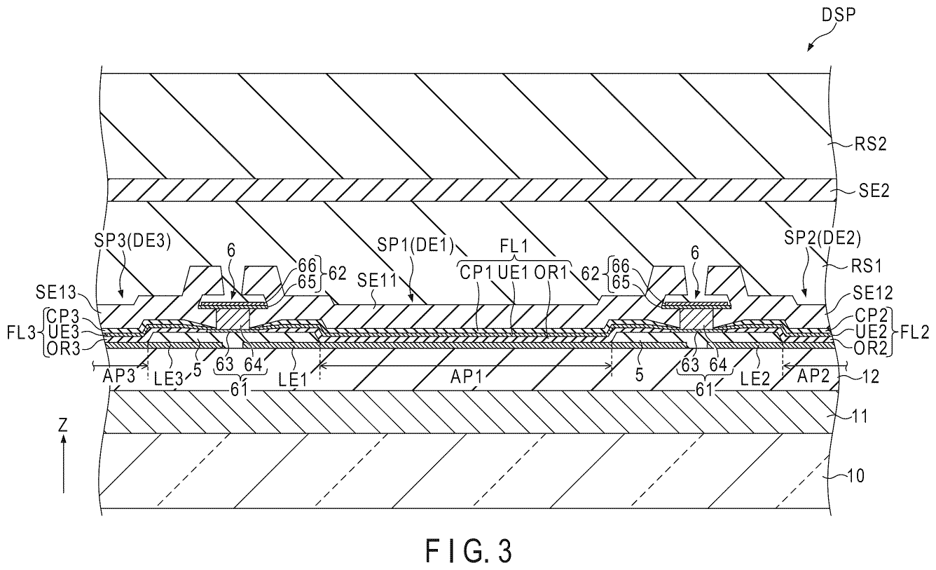

FIG. 3 is a schematic cross-sectional view of the display device DSP along the III-III line of FIG. 2. A circuit layer 11 is provided on the substrate 10. The circuit layer 11 includes various circuits and lines such as the pixel circuit 1, the scanning lines G, the signal lines S, and the power lines PL shown in FIG. 1. The circuit layer 11 is covered with an organic insulating layer 12. The organic insulating layer 12 functions as a planarization film, which planarizes the irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. The periphery portions of the lower electrodes LE1, LE2, and LE3 are covered with the rib layer 5. Although not shown in the section of FIG. 3, the lower electrodes LE1, LE2, and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. That is, the partition 6 has an overhang shape in which the both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, the both end portions of the bottom layer 63 protrude from the side surfaces of the stem layer 64.

In the example of FIG. 3, the upper portion 62 comprises a first top layer 65, and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2.

The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6.

The display element DE1 includes a cap layer CP1, which covers the upper electrode UE1. The display element DE2 includes a cap layer CP2, which covers the upper electrode UE2. The display element DE3 includes a cap layer CP3, which covers the upper electrode UE3. The cap layers CP1, CP2, and CP3 function as optical adjustment layers, which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 (the first to third sealing layers) are provided in the subpixels SP1, SP2, and SP3, respectively. The sealing layer SE11 continuously covers the display element DE1 and the partition 6 around the display element DE1.

The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. It should be noted that two of the sealing layers SE11, SE12, and SE13 may be in contact with each other above the partition 6.

For example, a gap is formed between each of the sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA). The electrodes that constitute the touch panel described above may be provided on the sealing layer SE2.

The organic insulating layer 12 is formed of an organic insulating material such as polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. For example, each of the organic layers OR1, OR2, and OR3 comprises a structure in which a hole injection layer, a hole transport layer, an electron blocking layer, a light emitting layer, a hole blocking layer, an electron transport layer, and an electron injection layer are stacked in order in the Z-direction. Each of the organic layers OR1, OR2, and OR3 may comprise another structure such as a tandem structure including a plurality of light emitting layers.

Each of the cap layers CP1, CP2, and CP3 has, for example, a multilayer structure with a plurality of stacked transparent layers. These transparent layers may include a layer formed of an inorganic material and a layer formed of an organic material. These transparent layers have refractive indices different from one another. For example, these transparent layers have the refractive indices different from those of the upper electrodes UE1, UE2, and UE3 and the sealing layers SE11, SE12, and SE13. At least one of the cap layers CP1, CP2, and CP3 may be omitted.

Each of the bottom layer 63 and the stem layer 64 of the partition 6 is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

The first top layer 65 of the partition 6 is formed of, for example, a metal material. The second top layer 66 of the partition 6 is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, ITO or IZO can be used. The upper portion 62 may comprise three or more layers. Alternatively, the upper portion 62 may consist of a single layer. The upper portion 62 may further include a layer formed of an insulating material.

Common voltage is applied to the partition 6. This common voltage is applied to each of the upper electrodes UE1, UE2, and UE3 in contact with the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light according to applied voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light exhibiting the same color (for example, white). In this case, the display device DSP may comprise color filters that convert light emitted from the light emitting layers into light exhibiting colors corresponding to the subpixels SP1, SP2, and SP3. The display device DSP may comprise a layer including a quantum dot that generates light exhibiting colors corresponding to the subpixels SP1, SP2, and SP3 by the excitation caused by the light emitted from the light emitting layers.

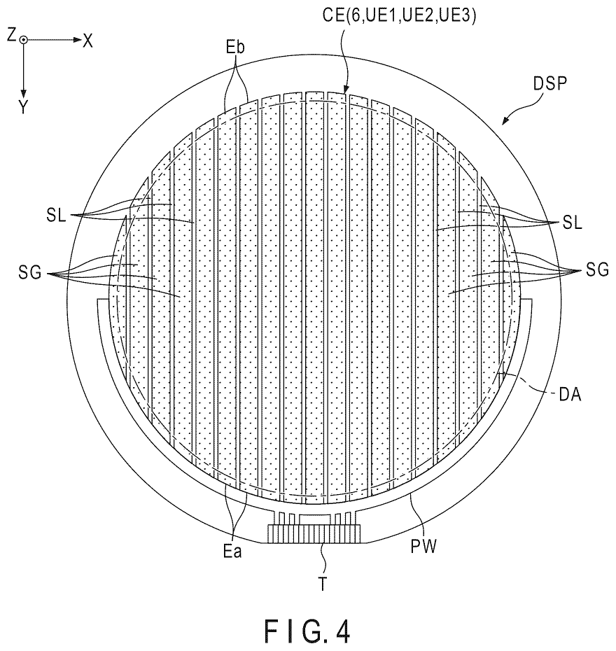

FIG. 4 is a schematic plan view showing some elements of the display device DSP. The partition 6 and the upper electrodes UE1, UE2, and UE3 constitute a common electrode CE, which applies common voltage to the display elements DE1, DE2, and DE3. The common electrode CE is, for example, circular, and entirely overlaps the display area DA.

The common electrode CE has a plurality of slits SL. At least one end of each of the slits SL reaches the outer edge of the common electrode CE (the outline in plan view). In the example of FIG. 4, both ends of the slit SL reach the outer edge of the common electrode CE. This causes the common electrode CE to be split into a plurality of segments SG spaced apart from one another via the slits SL.

In the example of FIG. 4, each slit SL extends in the Y-direction. As another example, each slit SL may extend in a direction parallel to the X-direction. The number of the slits SL provided in the common electrode CE is not particularly limited.

The intervals of the slits SL in the X-direction are, for example, constant. In this case, the widths of the segments SG in the X-direction are also constant. As another example, the interval of the slits SL or the widths of the segments SG may not be constant.

Each segment SG has a first end portion Ea and a second end portion Eb in the extension direction of the slits SL (the Y-direction in the present embodiment). The first end portion Ea is connected to a power supply line PW provided in the surrounding area SA. The power supply line PW is connected to the terminal portion T. Common voltage is applied to each of the segments SG from the terminal portion T via the power supply line PW. In the example of FIG. 4, the second end portions Eb of the segments SG are spaced apart from one another via the slits SL and are not connected by a conductive member such as the power supply line PW.

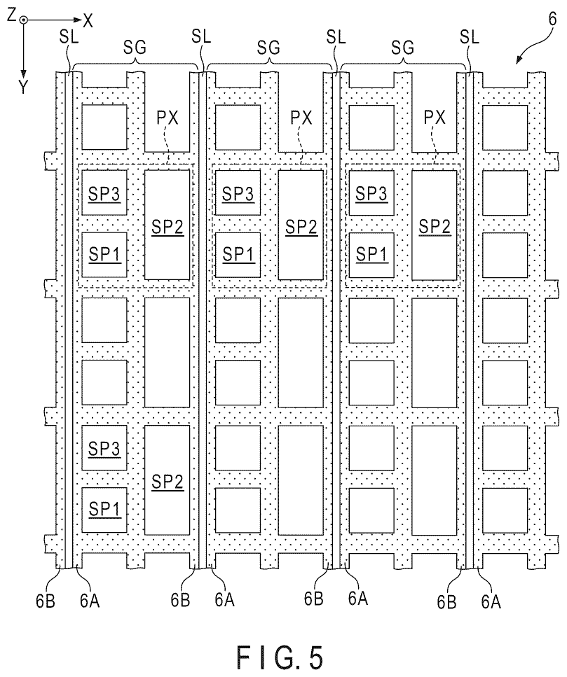

FIG. 5 is a schematic plan view showing an example of configurations applicable to the partition 6 according to the present embodiment. The slits SL are provided in portions extending in a direction parallel to the Y-direction in the partition 6.

Specifically, in the example of FIG. 5, each slit SL is provided in the portion located between pixels PX adjacent to each other in the X-direction in the partition 6. That is, each of the slits SL passes between one of the subpixel SP1 and SP3 adjacent to each other in the X direction and the subpixel SP2.

The form of the slit SL is not limited to the example of FIG. 5. For example, two or more pixels PX arrayed in the X-direction may be located between adjacent slits SL.

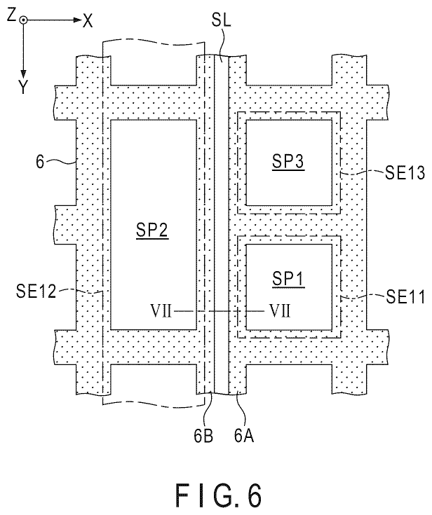

FIG. 6 is a schematic plan view showing an example of the relationship among the sealing layers SE11, SE12, and SE13 and the slit SL. The sealing layers SE11 and SE12 are formed into an island-like shape in the subpixels SP1 and SP3, respectively. The sealing layer SE12 is, for example, continuously formed over the plurality of subpixels SP2 arrayed in the Y-direction. As another example, the sealing layer SE12 may be formed per subpixel SP2.

The end portions of the sealing layers SE11, SE12, and SE13 are located on the partition 6 as a whole. In the example of FIG. 6, none of the sealing layers SE11, SE12, and SE13 overlaps the slit SL. At least one of the sealing layers SE11, SE12, and SE13 may overlap the slit SL.

The slit SL passes through the area located between the sealing layer SE11 and the sealing layer SE12 and between the sealing layer SE13 and the sealing layer SE12 and extends in the Y-direction. Of the partition 6, the portion in which the slit SL is provided is split into a first partition 6A on the subpixel SP1 side (or in the subpixel SP3 side) and a second partition 6B on the subpixel SP2 side.

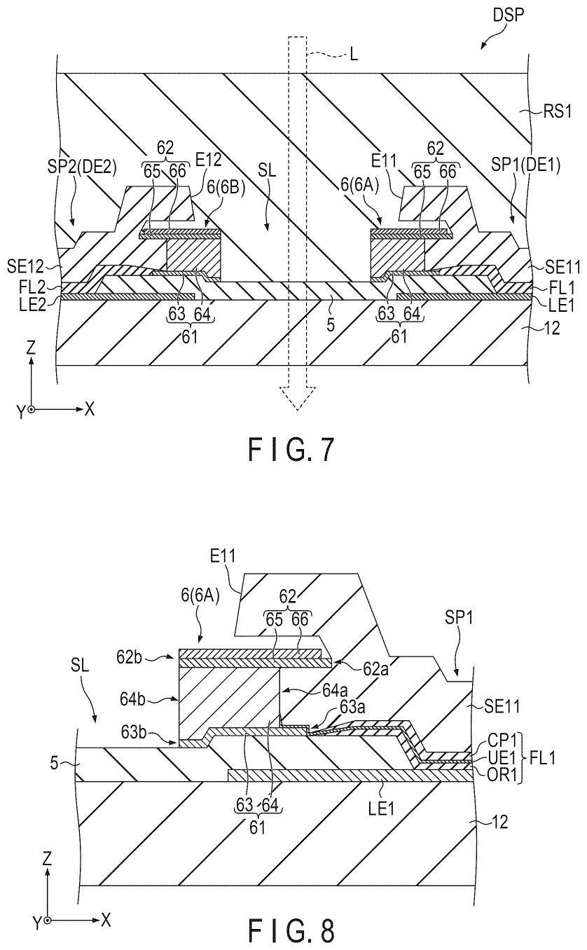

FIG. 7 is a schematic cross-sectional view of the display device DSP along the VII-VII line of FIG. 6. This figure omits the elements located under the organic insulating layer 12 and the elements located above the resin layer RS1.

As shown in FIG. 7, the partitions 6A and 6B each include the lower portion 61 and the upper portion 62. Further, in both of the partitions 6A and 6B, the lower portion 61 includes a bottom layer 63 and a stem layer 64, and the upper portion 62 includes a first top layer 65 and a second top layer 66.

An end portion E11 of the sealing layer SE11 is located above the first partition 6A. An end portion E12 of the sealing layer SE12 is located above the second partition 6B. The sealing layer SE11 continuously covers the stacked film FL1 of the subpixel SP1 and part of the first partition 6A. The sealing layer SE12 continuously covers the stacked film FL2 of the subpixel SP2 and part of the second partition 6B.

For example, the rib layer 5 is not open in the slit SL. In this case, the slit SL entirely overlaps the rib layer 5. For example, the slit SL is filled with the resin layer RS1. The resin layer RS1 contacts the rib layer 5 in the slit SL.

None of the lower electrodes LE1, LE2, and LE3 overlaps the slit SL. For this reason, external light L, which enters the slit SL, passes through the slit SL to the lower side without being blocked by the partition 6 or the lower electrode LE1, LE2, or LE3.

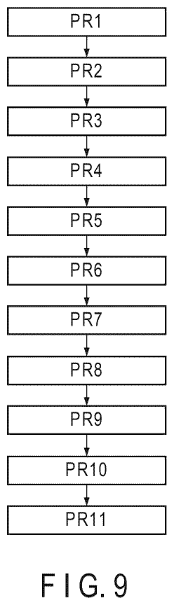

FIG. 8 is a schematic cross-sectional view showing the first partition 6A according to the present embodiment in enlarged manner. The stem layer 64 of the first partition 6A has a first side surface 64a on the subpixel SP1 side and a second side surface 64b on the slit SL side. The upper portion 62 of the first partition 6A has a first end portion 62a on the subpixel SP1 side and a second end portion 62b on the slit SL side. The bottom layer 63 of the first partition 6A has a third end portion 63a on the subpixel SP1 side and a fourth end portion 63b on the slit SL side.

The first end portion 62a and the second end portion 62b include end portions of the first top layer 65 and the second top layer 66. In the example of FIG. 8, the end portion of the second top layer 66 is slightly retracted with respect to the end portion of the first top layer 65 at the first end portion 62a. Further, at the second end portion 62b, the end portion of the first top layer 65 and the end portion of the second top layer 66 align. Alternatively, at the first end portion 62b, the end portion of the first top layer 65 and the end portion of the second top layer 66 may align. Alternatively, at the second end portion 62b, the end portion of the first top layer 65 and the end portion of the second top layer 66 may be diverge.

The first end portion 62a protrudes from the first side surface 64a. That is, of the first partition 6A, a portion in the subpixel SP1 side has the same overhang shape of the partition 6 shown in FIG. 3. In contrast, the second end portion 62b does not protrude from the second side surface 64b. In the example of FIG. 8, the second end portion 62b and the second side surface 64b align. As another example, the second end portion 62b may be retracted with respect to the second side surface 64b.

The third end portion 63a protrudes from the first side surface 64a. In contrast, the fourth end portion 63b does not protrude from the second side surface 64b. In the example of FIG. 8, the fourth end portion 63b and the second side surface 64b align. As another example, the fourth end portion 63b may be retracted with respect to the second side surface 64b.

At least part of the third end portion 63a is covered with the upper electrode UE1. In the example of FIG. 8, part of the first side portion 64a is covered with the upper electrode UE1. The sealing layer SE11 covers part of the first side surface 64a that is not covered with the upper electrode UE1 and the first end portion 62a. Similarly to the example of FIG. 3, a gap may be formed between the sealing layer SE11 and the upper portion 62. As another example, the stacked film FL1 may be provided at least part of the gap. The second end portion 62b, the fourth end portion 63b, and the second side surface 64b are covered with the resin layer RS1 (refer to FIG. 7).

The second partition 6B has the shape symmetric with the first partition 6A with respect to the slit SL. That is, the side portion of the second partition 6B on the subpixel SP2 side has the overhang shape, and in contrast, the side portion on the slit SL side has a shape different from the overhang shape.

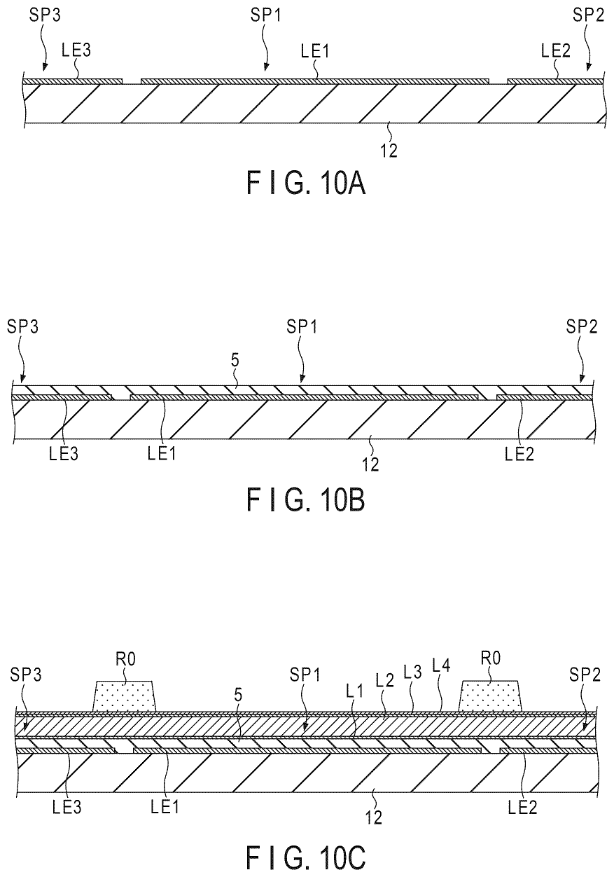

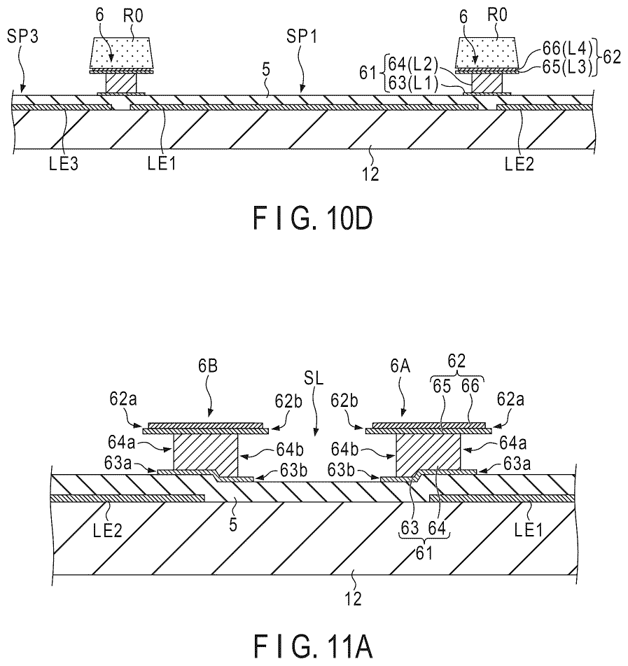

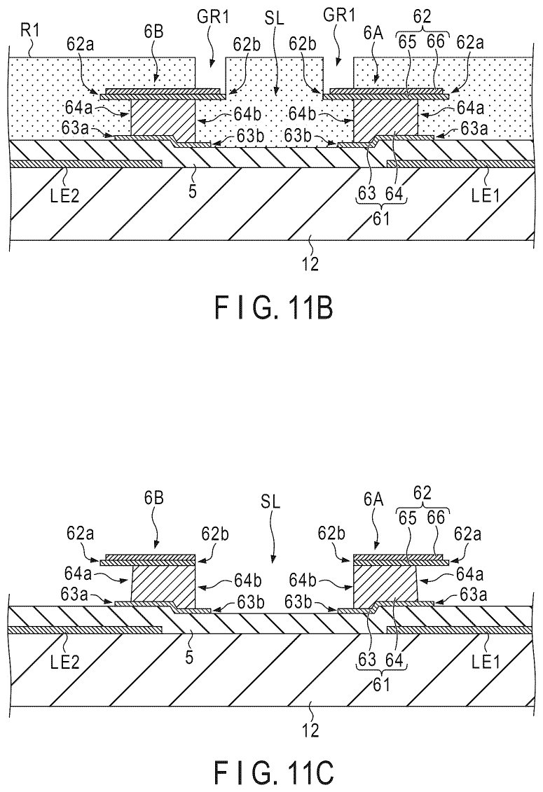

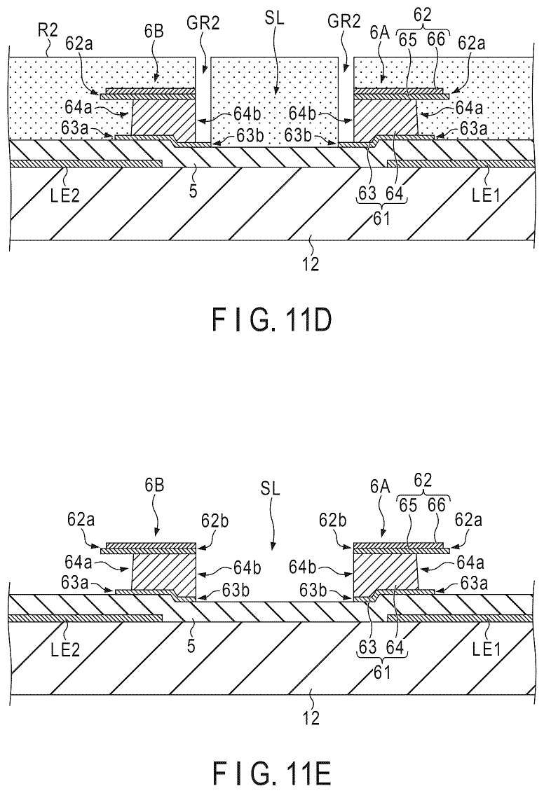

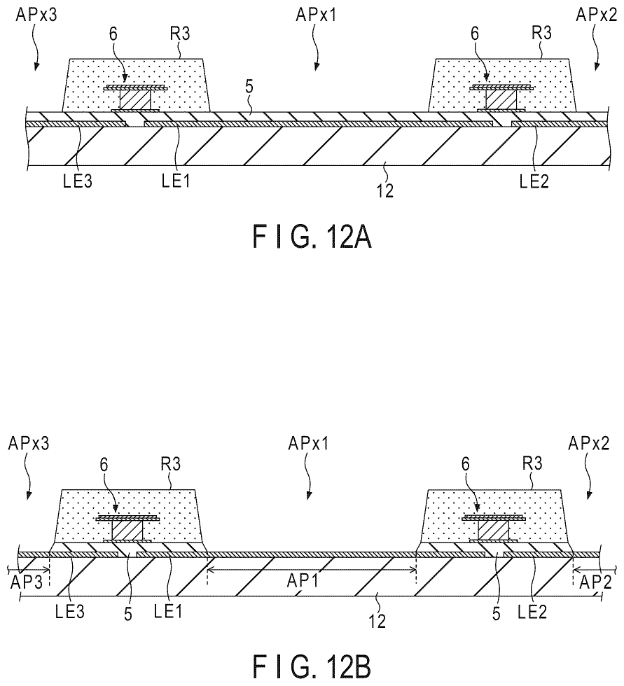

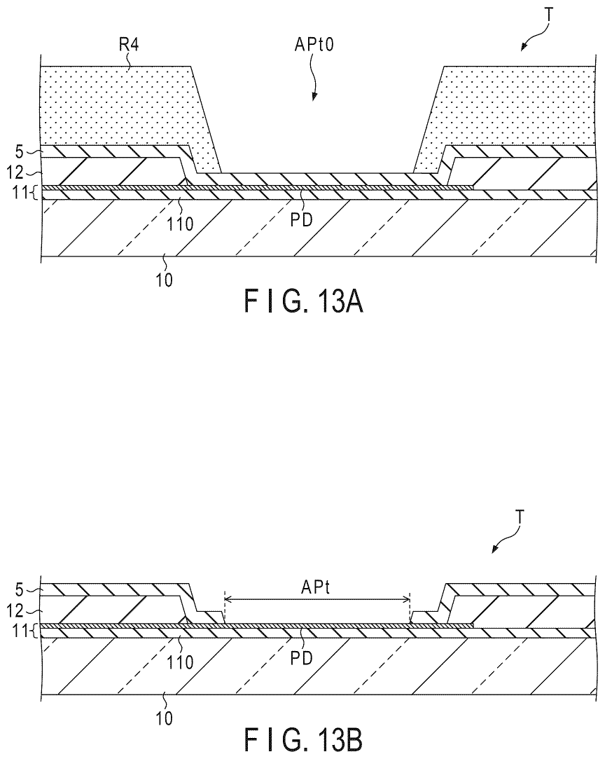

Now, this specification explains an example of the manufacturing method of the display device DSP. FIG. 9 is a flowchart showing an example of the manufacturing method of the display device DSP. Each of FIG. 10A to FIG. 10D, FIG. 11A to FIG. 11E, FIG. 12A, FIG. 12B, FIG. 13A, FIG. 13B, and FIG. 14A to FIG. 14D is a schematic cross-sectional view showing the manufacturing processes of the display device DSP. These cross-sectional views omit the illustration of the elements of the lower side of the organic insulating layer 12.

In the manufacturing of the display device DSP, first, the circuit layer 11 and the organic insulating layer 12 are formed on the substrate 10 (the process PR1 in FIG. 9). Subsequently, as shown in FIG. 10A, the lower electrodes LE1, LE2, and LE3 are formed on the organic insulating layer 12 (the process PR2 in FIG. 9).

Subsequently, as shown in FIG. 10B, the rib layer 5, which covers the lower electrodes LE1, LE2, and LE3 is formed (the process PR3 in FIG. 9). At this time, the pixel apertures AP1, AP2, and AP3 are not provided in the rib layer 5. The rib layer 5 may be formed by chemical vapor deposition (CVD).

After the formation of the rib layer 5, a process for forming the partition 6 is performed (the process PR4 in FIG. 9). In the process PR4, as shown in FIG. 10C, a first layer L1 processed to be the bottom layer 63, a second layer L2 processed to be the stem layer 64, a third layer L3 processed to be the first top layer 65, and a fourth layer L4 processed to be the second top layer 66 are formed on the rib layer 5 in order. Further, a resist RO is provided on the fourth layer L4. The resist RO has been patterned into the shape of the partition 6. The first layer L1, the second layer L2, the third layer L3, and the fourth layer L4 are formed by, for example, sputtering.

Subsequently, the first layer L1, the second layer L2, the third layer L3, and the fourth layer L4 are patterned using the resist RO as a mask. For example, the first layer L1 is formed of a titanium nitride. The second layer L2 is formed of aluminum. The third layer L3 is formed of titanium. The fourth layer L4 is formed of ITO. In this case, the above patterning process may include wet etching for removing the portion of the fourth layer L4 that is exposed from the resist RO, dry etching for removing the portions of the first, second, and third layers L1, L2, and L3 that are exposed from the resist RO, and wet etching for reducing the width of the second layer L2.

The process PR4 completes the partition 6 as shown in FIG. 10D. After the formation of the partition 6, the resist RO is removed (stripped). In the above wet etching for reducing the width of the second layer L2, the second top layer 66 (the fourth layer L4) could be slightly corroded as well. When this corrosion occurs, the width of the second top layer 66 becomes less than that of the first top layer 65.

The partitions 6A and 6B also are formed by the processes shown in FIG. 10C and FIG. 10D. FIG. 11A shows the partitions 6A and 6B immediately after the formation. At this time, in both of the partitions 6A and 6B, both of the second end portion 62b of the upper portion 62 and the fourth end portion 63b of the bottom layer 63 protrude from the second side surface 64b of the stem layer 64.

After the process PR4, the end portion of the upper portion 62 along the slit SL is removed in each of the partitions 6A and 6B (the process PR5 in FIG. 9). For example, the process PR5 may adopt the method shown in FIG. 11B to FIG. 11E.

That is, as shown in FIG. 11B, the resist R1 (the first resist) covering the rib layer 5 and the partitions 6A and 6B is formed first as shown in FIG. 11B. The resist R1 has a groove GR1 of the shape corresponding to the second end portion 62b of the upper portion 62 (a part protruding from the second side surface 64b). The second end portion 62b is exposed from the resist R1 through the groove GR1. In contrast, the first end portion 62a of the upper portion 62 is covered with the resist R1. For example, the groove GR1 extends in the Y direction along the slit SL.

Next, the first etching removes a part of the upper portion 62 that is exposed from the resist R1 through the groove GR1. After the first etching, the resist R1 is removed (stripped). Thus, as shown in FIG. 11C, the second end portion 62b of the partitions 6A and 6B are retracted to align with the second side surface 64b.

The first etching may be wet etching or dry etching that corrode both of the first top layer 65 and the second top layer 66. As another example, the first etching may include wet etching or dry etching for the second top layer 66 and wet etching or dry etching for the first top layer 65.

Next, as shown in FIG. 11D, a resist R2 (the second resist) covering the rib layer 5 and the partitions 6A and 6B is formed. The resist R2 has a groove GR2 of the shape corresponding to the fourth end portion 63b of the bottom layer 63 (a portion protruding from the second side surface 64b). The fourth end portion 63b is exposed from the resist R2 through the groove GR2. In contrast, the third end portion 63a of the bottom layer 63 is covered with the resist R2. For example, the groove GR2 extends in the Y direction along the slit SL.

Next, the second etching removes a part of the bottom layer 63 that is exposed from the resist R2 through the groove GR2. After the second etching, the resist R2 is removed (stripped). Thus, as shown in FIG. 11E, the fourth end portion 63b of the partitions 6A and 6B are retracted to align with the second side surface 64b.

The above process PR5 shown in FIG. 11A to FIG. 11E is performed on all of the partitions 6A and 6B split by the plurality of slits SL provided in the partition 6, for example. As another example, the process PR5 may be performed on the partitions 6A and 6B split by part of the slits SL.

At least part of the first groove GR1 and the second groove GR2 may overlap the stem layer 64 in plan view. In this case, the first etching or the second etching may corrode part of the stem layer 64 that overlaps the first groove GR1 or the second groove GR2.

After the process PR5, a process for providing the pixel apertures AP1, AP2, and AP3 is performed (the process PR6 in FIG. 9). FIG. 12A and FIG. 12B show an example of the flow of the process PR6. In the process PR6, as shown in FIG. 12A, a resist R3 covering the partition 6 is formed. The resist R3 has apertures APx1, APx2, and APx3 respectively overlapping the lower electrodes LE1, LE2, and LE3.

Further, etching for the rib layer 5 is performed using the resist R3 as a mask. For example, the etching is dry etching but may be the combination of dry etching and wet etching. As shown in FIG. 12B, the etching forms the pixel apertures AP1, AP2, and AP3 having the shapes respectively corresponding to the apertures APx1, APx2, and APx3 in the rib layer 5. Subsequently, the resist R3 is removed (stripped).

After the process PR6, a process for removing the rib layer 5 in the terminal portion T is performed (the process PR7 in FIG. 9). FIG. 13A and FIG. 13B show an example of the flow of the process PR7.

As shown in FIG. 13A and FIG. 13B, the terminal portion T comprises a conductive pad PD. The pad PD is provided on an insulating layer 110 formed of, for example, an inorganic insulating material. The pad PD and the insulating layer 110 are included in the circuit layer 11 shown in, for example, FIG. 3. For example, the peripheral portion of the pad PD is covered with the organic insulating layer 12.

At the time point when the process PR6 is completed, as shown in FIG. 13A, the pad PD is covered with the rib layer 5. In the process PR7, a resist R4 of a shape that is open above the pad PD is provided on the rib layer 5. The resist R4 has an aperture APt0 overlapping the pad PD.

Further, etching for the rib layer 5 is performed using the resist R4 as a mask. The etching is, for example, dry etching. As shown in FIG. 13B, this process forms a terminal aperture APt from which the pad PD is exposed in the rib layer 5. After the dry etching described above, the resist R4 is removed (stripped).

The process PR7 may form an aperture in the rib layer 5 from which the pads other than the terminal portion T are exposed. Examples of such pads include inspection pad for inspection of image display.

After the process PR7, a process of forming the display elements DE1, DE2, and DE3 is performed (the processes PR8, PR9, and PR10 in FIG. 10). FIG. 14A to FIG. 14D show an example of the flow of the processes PR8, PR9, and PR10.

In the formation of the display element DE1, first, as shown in FIG. 14A, the stacked film FL1 and the sealing layer SE11 are formed on the entire substrate 10. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. The organic layer OR1, the upper electrode UE1, and the cap layer CP1 may be formed by, for example, vapor deposition. The sealing layer SE11 may be formed by, for example, CVD. The stacked film FL1 is split into a plurality of portions by the partition 6 having an overhang shape. The sealing layer SE11 continuously covers the portions into which the stacked film FL1 is split and the partition 6.

Subsequently, the stacked film FL1 and the sealing layer SE11 are patterned. In this patterning, as shown in FIG. 14A, a resist R5 is provided on the sealing layer SE11. The resist R5 covers the subpixel SP1 and part of the partition 6 around the subpixel SP1.

Subsequently, etching using the resist R5 as a mask is performed. As shown in FIG. 14B, this etching removes the parts of the stacked film FL1 and the sealing layer SE11 that are exposed from the resist R5. This forms the display element DE1 in the subpixel SP1. This etching could include wet etching and dry etching processes that are performed in order for the sealing layer SE11, the cap layer CP1, the upper electrode UE1, and the organic layer OR1. After these etching processes, the resist R5 is removed (stripped).

The display elements DE2 and DE3 can be formed by a procedure similar to that of the display element DE1. Specifically, in the formation of the display element DE2, the stacked film FL2 and the sealing layer SE12 are formed on the entire mother substrate MB. The stacked film FL2 includes, as shown in FIG. 3, the organic layer OR2 contacting the lower electrode LE2 through the pixel aperture AP2, the upper electrode UE2 covering the organic layer OR2, and the cap layer CP2 covering the upper electrode UE2. Patterning these stacked film FL2 and sealing layer SE2 forms the subpixel SP2 in the display element DE2 as shown in FIG. 14C.

Specifically, in the formation of the display element DE3, the stacked film FL3 and the sealing layer SE13 are formed in the entire mother substrate MB. As shown in FIG. 3, the stacked film FL3 includes the organic layer OR3 contacting the lower electrode LE3 through the pixel aperture AP3, the upper electrode UE3 covering the organic layer OR3, and the cap layer CP3 covering the upper electrode UE3. Patterning these stacked film FL3 and sealing layer SE13 forms the display element DE3 in the subpixel SP3 as shown in FIG. 14D.

The above assumes cases where the display elements DE1, DE2, and DE3 are formed in this order. However, the display elements DE1, DE2, and DE3 may be formed in another order.

After the process PR10, the resin layer RS1, the sealing layer SE2, and the resin layer RS2 are formed in order (the process PR11 in FIG. 9). The resin layers RS1 and RS2 may be formed by, for example, an ink-jet method. For example, the sealing layer SE2 can be formed by CVD. The above processes complete the display device DSP.

Now, this specification explains some effects obtained from the display device DSP according to the present embodiment.

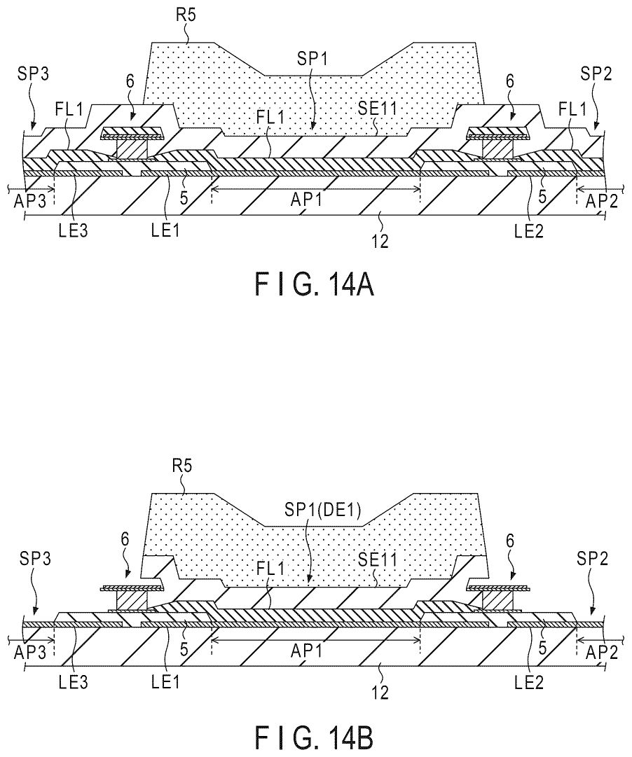

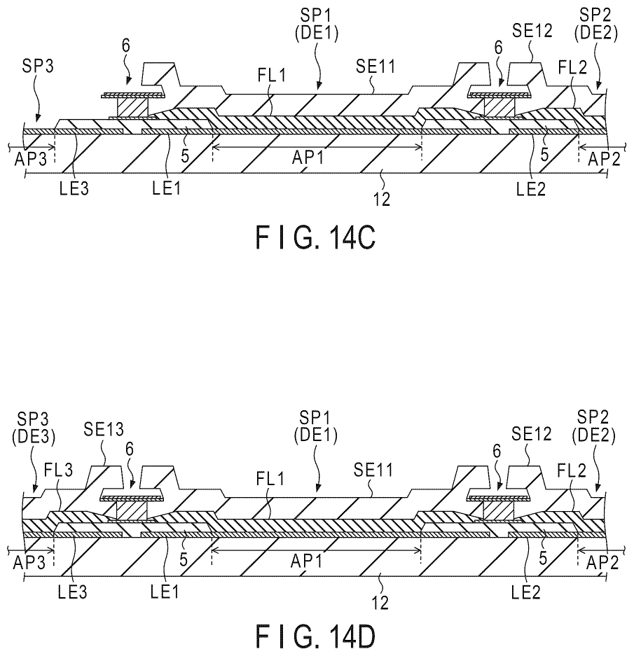

FIG. 15 and FIG. 16 are diagrams for explaining the effect of the display device DSP according to the present embodiment. An electronic device on which the display device DSP is mounted may comprise an antenna AT1 for near field communication (NFC). For example, the antenna AT1 is provided to face the rear side of the display device DSP (the lower surface of the substrate 10 shown in FIG. 3) and wirelessly communicates with the antenna AT2 of another electronic device through the display device DSP.

Magnetic field M1 formed by the antenna AT1 generates eddy current I in the common electrode CE at the time of wireless communication between the antennas AT1 and AT2. The eddy current I forms magnetic field M2, which negates magnetic field M1 and attenuates the signal strength. Thus, wireless communication performed via the display device DSP could result in a decrease in the communication sensitivity. In particular, the resistance of the common electrode CE becomes low in cases where the partition 6 mainly formed of a metal material and having a grating shape is formed in the entire display area DA. This generates large eddy current I and strong magnetic field M2 in association with it, making the communication sensitivity easily decreased.

To the contrary, in the present embodiment, the common electrode CE is split into the plurality of segments SG by the slits SL. This configuration prevents a large eddy current from being easily generated in the common electrode CE, suppressing the decrease in communication sensitivity. Eddy current could be generated in each segment SG. However, the effect caused to communication sensitivity by this eddy current is tiny compared to eddy current I generated in the entire part of a common electrode CE that is not split.

Electronic devices on which the display device DSP is mounted may comprise an optical sensor SN such as an illumination sensor, which detects external light. When the optical sensor SN is provided on the rear side of the display device DSP, the display device DSP needs to have translucency.

However, each of the lower electrodes LE1, LE2, and LE3 includes the reflective layer described above. In addition, the partition 6, which is at least partly formed of a metal material, has light-shielding properties. For this reason, the light made incident on the display surface of the display device DSP could be mostly reflected or blocked without being transmitted to the rear side.

To the contrary, when the slits SL are provided in the partition 6 like the present embodiment, as in the case of external light L shown in FIG. 7, part of the light made incident on the display surface is transmitted to the rear side of the display device DSP through the slits SL. This configuration can enhance the translucency of the display device DSP.

In this manner, the present embodiment can provide the display device DSP that has a higher compatibility with an antenna for wireless communication and an optical sensor. Moreover, as explained below, the present embodiment can improve the yield of the display device DSP.

In the present embodiment, the process PR5 shown in FIG. 11A to FIG. 11E make the second end portion 62b of the partitions 6A and 6B retracted to the vicinity of the second side surface 64b. If this process is not adopted, as shown in FIG. 11A, the stacked films FL1, FL2, and FL3 and the sealing layers SE11, SE12, and SE13, and resistors for processing these are formed on the partitions 6A and 6B with both side surfaces of the overhang shape, in the processes PR8 to PR10. In this case, air bubbles may enter the lower side of the second end portion 62b along the slit SL. Air bubbles that burst in the reduced-pressure drying process and the like make areas that should be normally covered with the resist exposed. The exposed areas may corrode in the subsequent etching processes.

Further, if the side portions of the partitions 6A and 6B along the slit has the overhang shape, air bubbles may enter the lower side of the second end portion 62b in the formation of the resin layer RS1 as well. These air bubbles may deform the resin layer RS1. For example, air bubbles exiting from the resin layer RS1 forms a hollow along the slit in the resin layer RS1.

In contrast, when the process PR5 makes the second end portion 62b of the partitions 6A and 6B along the slit SL retracted, like the present embodiment, air bubbles are less likely to enter the lower side of the resist and the resin layer RS1. This configuration can suppress the deformation in the vicinity of the slit SL due to air bubbles, improving the yield of the display device DSP.

In the present embodiment, as shown in FIG. 11D and FIG. 11E, the fourth end portion 63b of the bottom layer 63 along the silt SL retracts to the vicinity of the second side portion 64b. This increases transmissive areas in the slit SL, further increasing light transmitting property of the display device DSP.

### Second Embodiment

The first embodiment describes as examples the cases where the process PR5 shown in FIG. 11A to FIG. 11E is performed between the process PR4 for forming the partition 6 and the process PR6 for forming the pixel apertures AP1, AP2, and AP3 in the rib layer 5. However, the timing at which the process PR5 is performed is not limited to this example.

For example, the process PR5 can be performed at the same time of one or both of the process PR6 of forming the pixel apertures AP1, AP2, and AP3 in the rib layer 5 and the process PR7 of forming the terminal aperture APt in the rib layer 5.

For example, the etching in the process PR6, which forms the pixel apertures AP1, AP2, and AP3 in the rib layer 5 may serve as the first etching process for the upper portion 62 in the process PR5. Further, the etching process in the process PR7, which forms the terminal aperture APt in the rib layer 5 may serve as the second etching process for the bottom layer 63 in the process PR5. In these cases, the resist R3 shown in FIG. 12A and FIG. 12B can serve as the resist R1 (the first resist) shown in FIG. 11B. Further, the resist R4 shown in FIG. 13A can serve as the resist R2 (the second resist) shown in FIG. 11D.

As another example, the etching process of forming the terminal aperture APt in the rib layer 5 may serve as the first etching and then the second etching process may be performed after the process PR7. In this case, the resist R4 shown in FIG. 13A can serve as the resist R1 shown in FIG. 11B.

As still another example, the first etching process may be performed before the process PR6, and the etching, which forms the pixel apertures AP1, AP2, and AP3 in the rib layer 5 in the process PR6 may serve as the second etching process. In this case, the resist R3 shown in FIG. 12A can serve as the resist R2 shown in FIG. 11D.

In this manner, the configuration in which at least one of the etching processes for the rib layer 5 in the processes PR6 and PR7 serves as at least one of the first etching process and the second etching process can reduce the number of manufacturing processes.

The shapes of the partitions 6A and 6B are not limited to the examples shown in FIG. 7 and FIG. 8. The following third to fifth embodiments disclose other shapes applicable to the partitions 6A and 6B.

### Third Embodiment

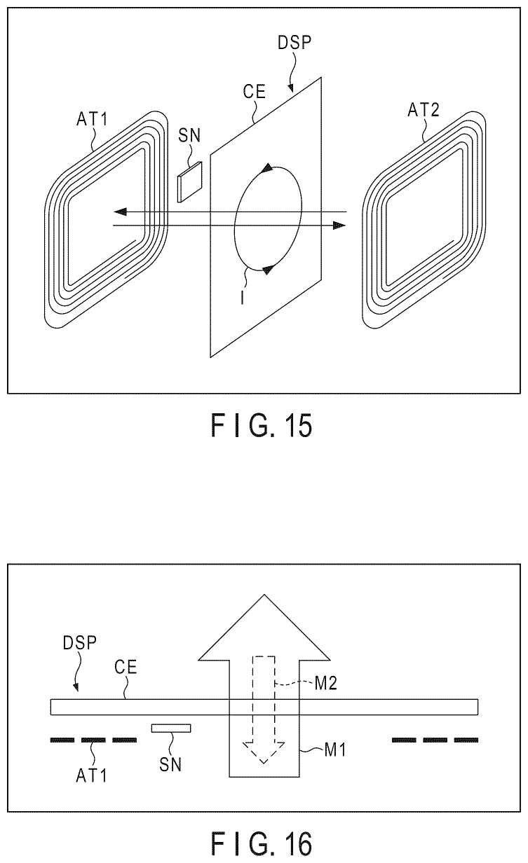

FIG. 17 is a schematic cross-sectional view showing a first partition 6A according to the third embodiment. This figure omits the illustration of the elements other than the organic insulating layer 12, the lower electrode LE1, the rib layer 5, and the first partition 6A. The same configuration as the first partition 6A is applicable to the second partition 6B.

In the example of FIG. 17, a second side surface 62b of an upper portion 62 protrudes from a second side surface 64b of a stem layer 64. Further, a fourth end portion 63b of a bottom layer 63 protrudes from the second side surface 64b.

Here, a protrusion length of a first end portion 62a from a first side surface 64a is defined as a protrusion length L1a, a protrusion length of the second end portion 62b from the second side surface 64b is defined as a protrusion length L1b, a protrusion length of a third end portion 63a from a first side surface 64a is defined as a protrusion length L2a, and a protrusion length of the fourth end portion 63b from the second side surface 64b is defined as a protrusion length L2b.

In the example of FIG. 17, the protrusion length L1a is greater than the protrusion length L2a (L1a>L2a). The protrusion length L1b is smaller than the protrusion length L1a (L1b<L1a). The protrusion length L2b is smaller than the protrusion length L2a (L2b<L2a). For example, the lengths L1b and L2b are equivalent to each other.

In this manner, even when the second end portions 62b and the fourth end portion 63b protrude from the second side surface 64b, the occurrence of air bubbles in the formation of the resist covering the partitions 6A and 6B and the resin layer RS1 can be suppressed as far as the protrusion length L1b is short, like the first embodiment. Further, when the protrusion length L2b is small as well, the transmissive in the slit SL is expected to increase.

### Fourth Embodiment

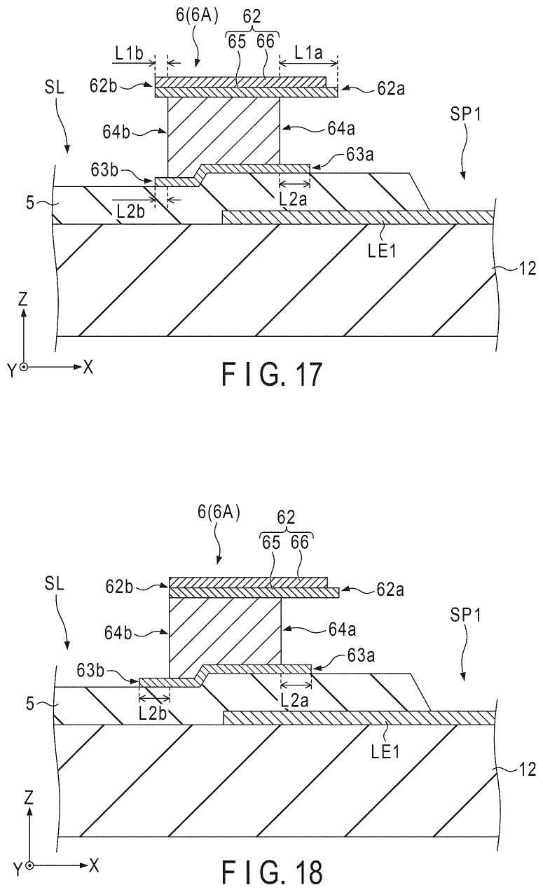

FIG. 18 is a schematic cross-sectional view showing a first partition 6A according to the fourth embodiment. This figure omits the illustration of the elements other than the organic insulating layer 12, the lower electrode LE1, the rib layer 5, and the first partition 6A. The same configuration as the first partition 6A is applicable to the second partition 6B.

In the example of FIG. 18, a second end portion 62b of an upper portion 62 and a second side surface 64b of a stem layer 64 align. In contrast, a fourth end portion 63b of a bottom layer 63 protrudes from the second side surface 64b.

For example, a protrusion length L2b of the fourth end portion 63b from the second side surface 64b is equivalent to a protrusion length L2a of a third end portion 63a from a first side surface 64a. In this case, the manufacturing of the display device DSP may omit the formation of the resist R2 shown in FIG. 11D and the second etching.

The configuration of FIG. 18 can suppress the occurrence of air bubbles in the formation of the resist covering the partitions 6A and 6B and the resin layer RS1, like the first embodiment.

### Fifth Embodiment

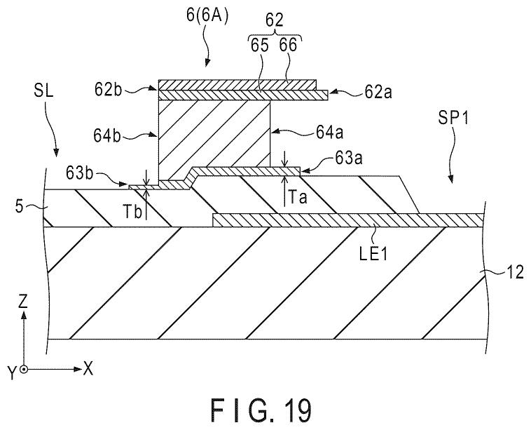

FIG. 19 is a schematic cross-sectional view showing a first partition 6A according to the fifth embodiment. This figure omits the illustration of the elements other than the organic insulating layer 12, the lower electrode LE1, the rib layer 5, and the first partition 6A. The same configuration as the first partition 6A is applicable to the second partition 6B.

In the example of FIG. 19, a second side surface 62b of an upper portion 62 and a second side surface 64b of a stem layer 64 align. In contrast, a fourth end portion 63b of a bottom layer 63 protrudes from the second side surface 64b. As in the example of FIG. 17, the second end portion 62b may slightly protrude from the second side surface 64b.

In the example of FIG. 19, a third end portion 63a of the bottom layer 63 has a thickness Ta. The fourth end portion 63b has a thickness Tb smaller than the thickness Ta (Tb<Ta).

The configuration of FIG. 19 also can suppress the occurrence of air bubbles in the formation of the resist covering the partitions 6A and 6B and the resin layer RS1 like the first embodiment. Further, in cases where the fourth end portion 63b is sufficiently thin, external light could pass through the fourth end portion 63b. Thus, the transmittance of the slit SL is expected to enhance as well.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device, comprising:
a first subpixel and a second subpixel that are arrayed in a first direction;
a rib layer having a first pixel aperture located in the first subpixel and a second pixel aperture located in the second subpixel;
a partition located between the first subpixel and the second subpixel and provided above the rib layer, wherein
the partition is split into a first partition on the first subpixel side and a second partition on the second subpixel side by a slit extending in a second direction intersecting the first direction,
the first partition comprises:
a lower portion having a first side surface on the first subpixel side and a second side surface on the slit side; and
an upper portion having a first end portion on the first subpixel side and a second end portion on the slit side and provided on the lower portion,
the first end portion protrudes from the first side surface, and
the second end portion does not protrude from the second side surface or protrudes from the second side surface with a protrusion length shorter than a protrusion length of the first end portion from the first side surface.

2. The display device of claim 1, wherein
the lower portion of the first partition comprises:
a stem layer having the first side surface and the second side surface; and
a bottom layer located between the rib layer and the stem layer and having a third end portion on the first subpixel side and a fourth end portion on the slit side, and
the third end portion protrudes from the first side surface.

3. The display device of claim 2, wherein
the fourth end portion dose not protrude from the second side surface.

4. The display device of claim 2, wherein
the fourth end portion protrudes from the second side surface.

5. The display device of claim 4, wherein
a protrusion length of the fourth end portion from the second side surface is shorter than a protrusion length of the third end portion from the first side surface.

6. The display device of claim 4, wherein
the fourth end portion is thinner than the third end portion.

7. The display device of claim 1, wherein
the first subpixel comprises:
a first lower electrode overlapping the first pixel aperture and having a peripheral portion covered with the rib layer;
a first organic layer covering the first lower electrode through the first pixel aperture and emitting light according to applied voltage; and
a first upper electrode covering the first organic layer and contacting the lower portion of the first partition.

8. The display device of claim 7, further comprising:
a first sealing layer formed of an inorganic insulating material and provided above the first upper electrode, and
the first sealing layer covers the first side surface and the first end portion.

9. The display device of claim 8, wherein
an end portion of the first sealing layer is located above the first partition.

10. The display device of claim 9, further comprising:
a resin layer covering the first sealing layer, wherein
the second side surface and the second end portion are covered with the resin layer.

11. The display device of claim 10, wherein
the resin layer contacts the rib layer in the slit.

12. The display device of claim 7, wherein
the second subpixel comprises:
a second lower electrode overlapping the second pixel aperture and having a peripheral portion covered with the rib layer;
a second organic layer covering the second lower electrode through the second pixel aperture and emitting light according to applied voltage; and
a second upper electrode covering the second organic layer and contacting the second partition.

13. The display device of claim 12, wherein
the slit does not overlap the first lower electrode and the second lower electrode.

14. A display device manufacturing method, comprising:
forming a first lower electrode and a second lower electrode respectively in a first subpixel and a second subpixel that are arrayed in a first direction;
forming a rib layer covering the first lower electrode and the second lower electrode;
forming a first partition on the first subpixel side and a second partition on the second subpixel side between the first subpixel and the second subpixel, the first partition and the second partition each having a lower portion provided above the rib layer and an upper portion having end portions respectively protruding from side surfaces of the lower portion and split by a slit extending in a second direction intersecting the first direction; and
removing an end portion of the upper portion along the slit on at least one of the first partition and the second partition.

15. The display device manufacturing method of claim 14, wherein
the lower portion of the first partition having a first side surface on the first subpixel side and a second side surface on the slit side,
the upper portion of the first partition has a first end portion on the first subpixel side and a second end portion on the slit side, and
the removing process includes:
providing a first resist covering the first end portion and making the second end portion exposed; and
removing at least part of the second end portion exposed from the first resist by a first etching.

16. The display device manufacturing method of claim 15, wherein
the lower portion of the first partition comprises:
a stem layer having the first side surface and the second side surface;
a bottom layer located between the rib layer and the stem layer and having a third end portion protruding from the first side surface and a fourth end portion protruding from the second side surface, and
the removing process includes:
removing the first resist after the first etching;
providing a second resist covering the third end portion and making the fourth end portion exposed, and
removing at least part of the fourth end portion exposed from the second resist by a second etching.

17. The display device manufacturing method of claim 15, wherein
the first resist has an aperture overlapping the first lower electrode and the second electrode, and
a first pixel aperture overlapping the first lower electrode and a second pixel aperture overlapping the second lower electrode are formed by removing the rib layer exposed through the aperture by the first etching.

18. The display device manufacturing method of claim 15, wherein
the rib layer covers a conductive pad provided outside a display area including the first subpixel and the second subpixel,
the first resist has an aperture overlapping the pad, and
the first etching forms a terminal aperture overlapping the pad in the rib layer by removing the rib layer exposed through the aperture.

19. The display device manufacturing method of claim 14, further comprising:
forming a first organic layer emitting light according to applied voltage in the first subpixel;
forming a first upper electrode covering the first organic layer and contacting the lower portion of the first partition; and
forming a first sealing layer formed of an inorganic insulating material above the first upper electrode.

20. The display device manufacturing method of claim 19, further comprising:
forming a resin layer covering the first sealing layer and contacting the rib layer in the slit.
